(19) United States
(12) Patent Application Publication
(10) Pub. No.: US 2025/0324595 A1
(43) Pub. Date: Oct. 16, 2025

(54) SEMICONDUCTOR DEVICES AND FABRICATION METHODS THEREOF

(71) Applicant: Yangtze Memory Technologies Co., Ltd., Wuhan (CN)

(72) Inventors: Kun ZHANG, Wuhan (CN); Wenxi ZHOU, Wuhan (CN); Tingting GAO, Wuhan (CN); Wei YUAN, Wuhan (CN); Zhiliang XIA, Wuhan (CN); Zongliang HUO, Wuhan (CN)

(21) Appl. No.: 18/769,180

(22) Filed: Jul. 10, 2024

(30) Foreign Application Priority Data
Apr. 15, 2024 (CN) 202410454233.2

(51) Int. Cl. H10B 43/27; H01L 23/528; H01L 23/532; H10B 43/10; H10B 43/35

(52) U.S. Cl. CPC H10B 43/27; H01L 23/5283; H01L 23/53295; H10B 43/10; H10B 43/35

(57) ABSTRACT

The present disclosure relates to methods, devices, systems, and techniques for managing channel hole and gate line merging in semiconductor devices. An example semiconductor device includes a first memory block, a second memory block, and at least a first gate line structure between the first memory block and the second memory block. Each of the first memory block and the second memory block includes a stack of conductive layers and insulating layers alternating with each other along a first direction. The first gate line structure insulates the conductive layers of the first memory block from the conductive layers of the second memory block. The first gate line structure includes gate line insulating layers spaced along the first direction and pillars that are spaced along a second direction perpendicular to the first direction and extend through the gate line insulating layers along the first direction.

### CROSS-REFERENCE TO RELATED APPLICATIONS

This application claims priority to Chinese Patent Application No. 202410454233.2, filed on Apr. 15, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems and techniques for managing channel hole and gate line merging in semiconductor devices.

One aspect of the present disclosure features a semiconductor device. The semiconductor device includes memory blocks and at least a first gate line structure. The memory blocks include at least a first memory block and a second memory block, where each of the first memory block and the second memory block includes a stack of conductive layers and insulating layers alternating with each other along a first direction. The first gate line structure is between the first memory block and the second memory block. The first gate line structure insulates the conductive layers of the first memory block from the conductive layers of the second memory block. The first gate line structure includes gate line insulating layers and pillars. The gate line insulating layers are spaced along the first direction. The pillars are spaced along a second direction perpendicular to the first direction and extend through the gate line insulating layers along the first direction.

In some implementations, the first gate line structure is in contact with a sidewall of the first memory block and a sidewall of the second memory block.

In some implementations, a gate line insulating layer of the gate line insulating layers is between a corresponding conductive layer of the first memory block and a corresponding conductive layer of the second memory block.

In some implementations, a pillar of the pillars includes an outer layer and an inner structure surrounded by the outer layer, the outer layer includes a dielectric material, and the inner structure includes at least one of a polycrystalline silicon material, a dielectric material, or a metal.

In some implementations, one of the gate line insulating layers includes a dielectric material.

In some implementations, the semiconductor device further includes a third memory block and a second gate line structure between the second memory block and the third memory block.

In some implementations, the semiconductor device further includes one or more other gate line structures, where the first memory block includes multiple memory fingers divided by the one or more other gate line structures.

In some implementations, the stack of conductive layers and insulating layers includes multiple decks stacked along the first direction, and each of the multiple decks includes a subset of the stack of conductive layers and insulating layers.

Another aspect of the present disclosure features a method including providing a semiconductor structure. The semiconductor structure includes a stack of conductive layers and insulating layers alternating with each other along a first direction; channel structures extending through the stack along the first direction, where the channel structures include at least a first array of channel structures and a second array of channel structures; and at least a first set of gate line holes extending through the stack along the first direction. The first set of gate line holes is between the first array of channel structures and the second array of channel structures. The first set of gate line holes is spaced along a second direction perpendicular to the first direction. The conductive layers are connected by conductive inner surfaces of the first set of gate line holes. The method further includes forming a first gate line space by etching off the conductive inner surfaces of the first set of gate line holes to expose and recess the conductive layers. The first gate line space includes: tunnels that are between the insulating layers and extend along the second direction; and the first set of gate line holes extending through the tunnels along the first direction. The method further includes forming a first gate line structure in the first gate line space.

In some implementations, the first gate line space divides the conductive layers into a first set of conductive layers extended through by the first array of channel structures and a second set of conductive layers extended through by the second array of channel structures.

In some implementations, the first gate line structure includes: gate line insulating layers in the tunnels; and pillars in the first set of gate line holes. Each of the pillars includes an outer layer connected to the gate line insulating layers and an inner structure surrounded by the outer layer.

In some implementations, forming the first gate line structure includes forming the gate line insulating layers and the outer layer of each of the pillars by depositing a dielectric material in the first gate line space through the first set of gate line holes. Forming the first gate line structure further includes forming the inner structure of each of the pillars by filling at least one of a polycrystalline silicon material, a dielectric material, or a metal into the first set of gate line holes.

In some implementations, providing the semiconductor structure includes: forming a stack of sacrificial layers and insulating layers alternating with each other along the first direction; forming gate line holes and channel holes by a same etching process; and forming the channel structures in the channel holes. The gate line holes and the channel holes extend through the stack of sacrificial layers and insulating layers along the first direction, and the gate line holes include the first set of gate line holes.

In some implementations, providing the semiconductor structure further includes removing the sacrificial layers and forming the conductive layers and the conductive inner surfaces of the first set of gate line holes by depositing at least one conductive material into the first set of gate line holes.

In some implementations, the channel structures further include a third array of channel structures, and the gate line holes further include a second set of gate line holes between the second array of channel structures and the third array of channel structures.

In some implementations, forming the channel structures in the channel holes includes:
filling the gate line holes and the channel holes with a sacrificial material; covering the gate line holes; removing the sacrificial material in the channel holes; and depositing a high-k material, a memory film, and a channel layer into each of the channel holes.

A further aspect of the present disclosure features a memory system including a memory device and a memory controller coupled to the memory device and configured to control the memory device. The memory device includes: memory blocks including at least a first memory block and a second memory block, where each of the first memory block and the second memory block includes a stack of conductive layers and insulating layers alternating with each other along a first direction; and at least a first gate line structure between the first memory block and the second memory block, where the first gate line structure insulates the conductive layers of the first memory block from the conductive layers of the second memory block. The first gate line structure includes: gate line insulating layers spaced along the first direction; and pillars that are spaced along a second direction perpendicular to the first direction and extend through the gate line insulating layers along the first direction.

In some implementations, a gate line insulating layer of the gate line insulating layers is between a corresponding conductive layer of the first memory block and a corresponding conductive layer of the second memory block.

In some implementations, a pillar of the pillars includes an outer layer and an inner structure surrounded by the outer layer, the outer layer includes a dielectric material, and the inner structure includes at least one of a polycrystalline silicon material, a dielectric material, or a metal.

In some implementations, the memory device further includes a third memory block and a second gate line structure between the second memory block and the third memory block.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIGS. 1A-1B illustrate an example semiconductor device.

FIGS. 2A-2G illustrate an example process of manufacturing a semiconductor device.

FIG. 3 illustrates a flow chart of an example process of manufacturing a semiconductor device.

FIG. 4 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher-density, a memory device (e.g., a 3D NAND flash memory) can be formed to have multiple decks, and each deck can have a larger number of layers. The high aspect ratio of such memory device may bring challenges to the manufacturing process. For example, channel holes and gate line holes can be formed in a same etching process using a same etching mask, which can be referred to as channel hole and gate line merging.

Implementations of the present disclosure provide example techniques for managing channel hole and gate line merging in a semiconductor device, e.g., by forming a gate line structure between two memory blocks of the semiconductor device. The gate line structure can insulate conductive layers of one memory block from conductive layers of another memory block. The gate line structure can include gate line insulating layers and pillars. In some cases, the gate line insulating layers can be spaced along a vertical direction. The pillars can be spaced along a horizontal direction perpendicular to the vertical direction and extend through the gate line insulating layers along the vertical direction.

Implementations of the present disclosure can provide one or more of the following technical advantages and/or benefits. Channel holes and gate line holes can be formed in a same etching process using a same etching mask, thereby improving the manufacturing process flow and reducing the fabrication costs. In addition, an overlay (OVL) shift problem can be resolved, and the process window can be enlarged. Further, a gate line structure can be formed between two memory blocks of a memory device to prevent the memory blocks (e.g., with high aspect ratios) from tilting or collapsing, which can improve the quality of the memory device and increase the production yield. For example, the gate line structure can have tier oxide that is connected to sidewalls of the memory blocks, thereby improving the stability of the memory blocks. The techniques can lead to better structural uniformity of the channel structures and improvement to the input/output (I/O) loading of outer hole in gate line slits of the memory device. Therefore, the fabrication cost of the memory device can be reduced, and a storage capacity per unit area of the memory device can be increased.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

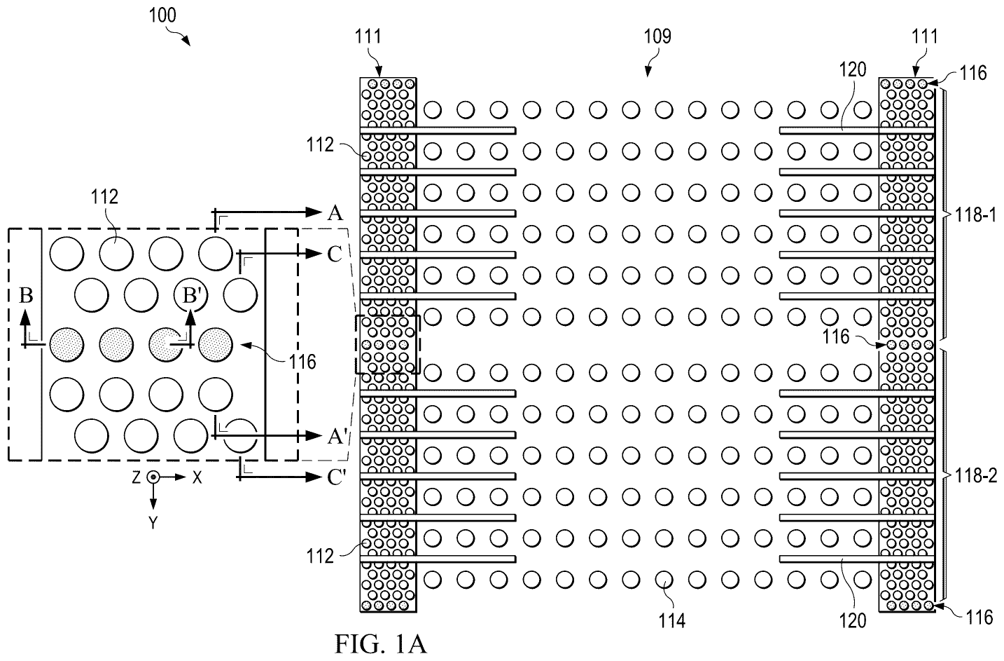

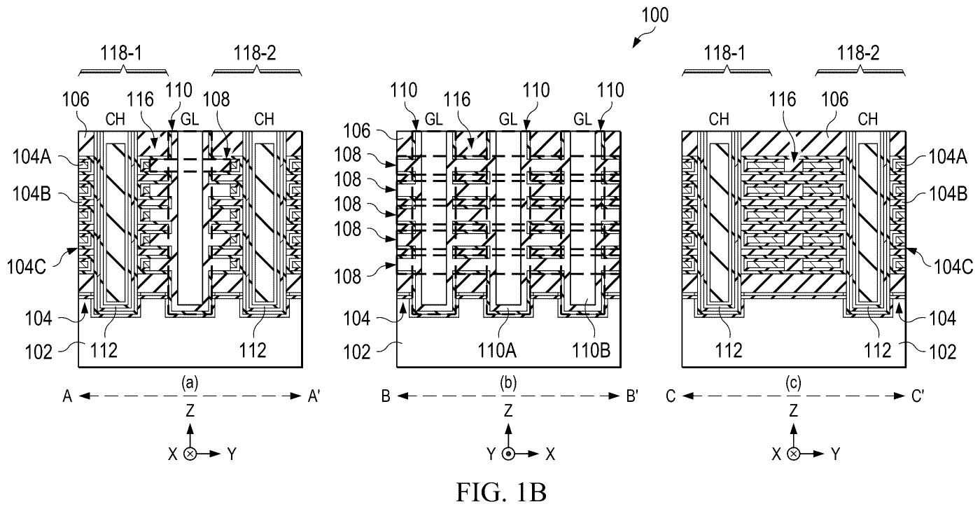

FIG. 1A illustrates a top view of an example semiconductor device 100. The semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes two array regions 111 and a connection region 109 between the two array regions along a first horizontal direction (e.g., the X direction). Each array region 111 can include an array of channel structures 112. Each channel structure 112 can be used to form a string of memory cells coupled in serial along a vertical direction (e.g., Z direction) perpendicular to the first horizontal direction. In some implementations, the connection region 109 can include a staircase structure (not shown) and an array of contact structures 114 formed on the staircase structure. In some other implementations, conductive layers (e.g., the conductive layers 104A in FIGS. 1B(a)-(c) as described below) in the connection region 109 form a structure different from a staircase structure. For example, a contact structure of the array of contact structures 114 can be connected to a corresponding conductive layer and can extend through other conductive layers, and spacer for insulation can be formed between the contact structure and the other conductive layers. In some implementations, gate line structures 116 extending in the X direction can divide an array region into multiple memory blocks (e.g., memory blocks 118-1 and 118-2 as shown in FIG. 1A). In some implementations, two adjacent portions 118-1 and 118-2 can be considered as a single memory block, and each of the portions 118-1 and 118-2 can be referred to as a memory finger. In some implementations, at least some gate line structures 116 can function as a common source contact for the channel structures 112 in the array regions 111. Top select gate (TSG) cuts 120 can be disposed, for example, in each of memory bocks 118-1 and 118-2 to divide the memory block into multiple portions. In some instances, each TSG cut 120 can extend through (e.g., along the vertical direction) one or more conductive layers in a top of a stack of alternating conductive layers and insulating layers (e.g., the stack 104 in FIGS. 1B(a)-(c) as described below) in the semiconductor device 100. In some implementations, the array regions 111 and the connection region 109 may include dummy channel structures or dummy memory strings (not shown) for process variation control during fabrication and/or for additional mechanical support.

It is noted that X, Y, and Z axes (also referred to as X, Y, and Z directions) are included in FIG. 1A to further illustrate the spatial relationship of various components in a semiconductor device. A substrate of the semiconductor device 100 can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIGS. 1B(a)-(c) illustrate cross-sectional views of the semiconductor device 100 along cut lines AA′, BB′, and CC′ of FIG. 1A, respectively. In some implementations, as illustrated in FIGS. 1B(a) and 1B(c), the semiconductor device 100 includes a substrate 102 and a stack 104 of alternating conductive layers 104A and insulating layers 104B provided over the substrate 102. The stack 104 can extend across both memory blocks 118-1 and 118-2. The substrate 102 can be any suitable semiconductor substrate having any suitable semiconductor material, such as monocrystalline, polycrystalline or single crystalline semiconductor. For example, the substrate 102 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. The semiconductor device 100 can include a top layer 106 made of an isolating material (e.g., oxide).

The stack 104 can extend in a second horizontal direction (e.g., Y direction) that is parallel to a top surface of the substrate 102 and perpendicular to the first horizontal direction. The conductive layers 104A and the insulating layers 104B can alternate in the vertical direction (e.g., Z direction) perpendicular to the second horizontal direction. The conductive layers 104A can be the same or different from each other in thickness, for example, ranging from 10-500 nm, e.g., about 35 nm. The insulating layers 104B can also be the same or different from each other in thickness, for example, ranging from 10-500 nm, e.g., about 25 nm. It should be noted that the number of the conductive layers 104A and the insulating layers 104B shown in FIG. 1B(a) or 1B(c) is for illustration only and that any suitable number of the conductive layers 104A and the insulating layers 104B can be included in the stack 104. In some implementations, the stack 104 can include multiple decks stacked along the vertical direction (e.g., the Z direction). Each of the multiple decks can include a subset of the conductive layers 104A and the insulating layers 104B in the stack 104. The conductive layers 104A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The insulating layers 104B can include a dielectric material, such as silicon oxide, silicon nitride, silicon oxynitride, or any combination thereof. In some implementations, the insulating layers 104B can also include high-K dielectric materials, such as hafnium oxide, zirconium oxide, aluminum oxide, tantalum oxide, lanthanum oxide, or any combination thereof.

In some implementations, as illustrated in FIG. 1B(a) or FIG. 1B(c), the stack 104 includes liner layers 104C. A liner layer 104C can cover part or all sides of a corresponding conductive layer 104A and be between the conductive layer 104A and two insulating layers 104B adjacent to the corresponding conductive layer 104A. The liner layer 104C can include a high-K dielectric material (e.g., Al₂O₃). In some examples, the conductive layer 104A includes a metallic material (e.g., W) and an adhesive material (e.g., TiN), and the adhesive material can be deposited between the metallic material and the high-K dielectric material. In some examples, the conductive layer 104A includes the metallic material (e.g., W), and the liner layer 104C includes the adhesive material (e.g., TiN) and the high-K dielectric material.

As shown in FIG. 1B(a) or FIG. 1B(c), each memory block (e.g., memory block 118-1 or 118-2) of the semiconductor device 100 includes channel structures 112 extending through the stack 104 and into the substrate 102 along the vertical direction. Each channel structure 112 can be in the shape of a cylinder or a pillar, and can include a high-K layer, a block layer surrounded by the high-K layer, a charge trapping layer (or a storage layer) surrounded by the block layer, a tunneling layer surrounded by the charge trapping layer, a channel layer surrounded by the tunneling layer, and a core filler layer surrounded by the channel layer, which extend through the conductive layers 104A and the insulating layers 104B of the stack 104, and a channel contact formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-k dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide).

As illustrated in FIG. 1A, one or more gate line structures 116 can be formed within the array region 111 in the first horizontal direction (e.g., the X direction) to divide the semiconductor device 100 into multiple memory blocks (e.g., memory blocks 118-1 and 118-2). Cross-sectional views of one of the gate line structures 116 are illustrated in FIGS. 1B(a)-(c). As shown in FIG. 1A, the gate line structure 116 extends along the first horizontal direction (e.g., the X direction) and is between the memory block 118-1 and the memory block 118-2. As shown in FIGS. 1B(a)-(c), the gate line structure 116 extends through the stack 104 and into the substrate 102 along the vertical direction (e.g., the Z direction) perpendicular to the first horizontal direction and the second horizontal direction. The gate line structure 116 can insulate the conductive layers 104A of the memory block 118-1 from the conductive layers 104A of the memory block 118-2. As shown in FIG. 1B(a), the gate line structure can be in contact with a sidewall of the memory block 118-1 and a sidewall of the memory block 118-2 along the Y direction.

In some implementations, the gate line structure 116 includes gate line insulating layers 108 spaced along the vertical direction (e.g., the Z direction) and pillars 110 that extend through the gate line insulating layers 108 along the vertical direction. Each gate line insulating layer 108 can be between a corresponding conductive layer 104A of the memory block 118-1 and a corresponding conductive layer 104A of the memory block 118-2 along the Y direction. In some implementations, each gate line insulating layer 108 can include a dielectric material (e.g., silicon oxide). The pillars 110 are spaced along the first horizontal direction (e.g., the X direction). As shown in FIGS. 1B(a) and 1B(b), each of the pillars 110 can include an outer layer 110A and an inner structure 110B surrounded by the outer layer 110A. In some implementations, the outer layer 110A can include a dielectric material (e.g., silicon oxide). The inner structure 110B can include at least one of a polycrystalline silicon material, a dielectric material, or a metal.

In some implementations, a size of a cross section of the pillar 110 can be larger than a size of a cross section of the channel structure 112. The cross section of the pillar 110 and the cross section of the channel structure 112 are perpendicular to the Z direction. The cross section of the pillar 110 and the cross section of the channel structure 112 can be at a same position along the Z direction. In some other implementations, the size of the cross section of the pillar 110 can be equal to the size of the cross section of the channel structure 112. In some implementations, the size of the cross section of the pillar 110 can be smaller than the size of the cross section of the channel structure 112.

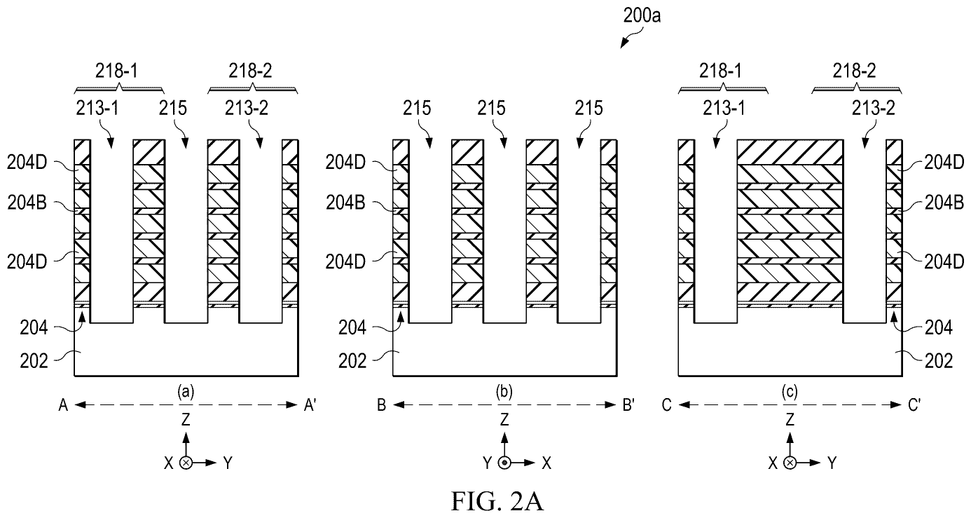

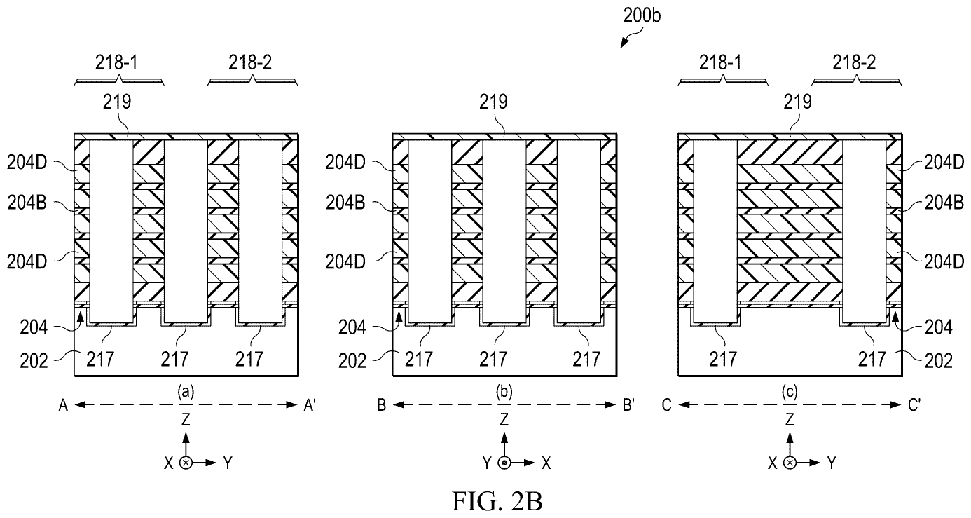

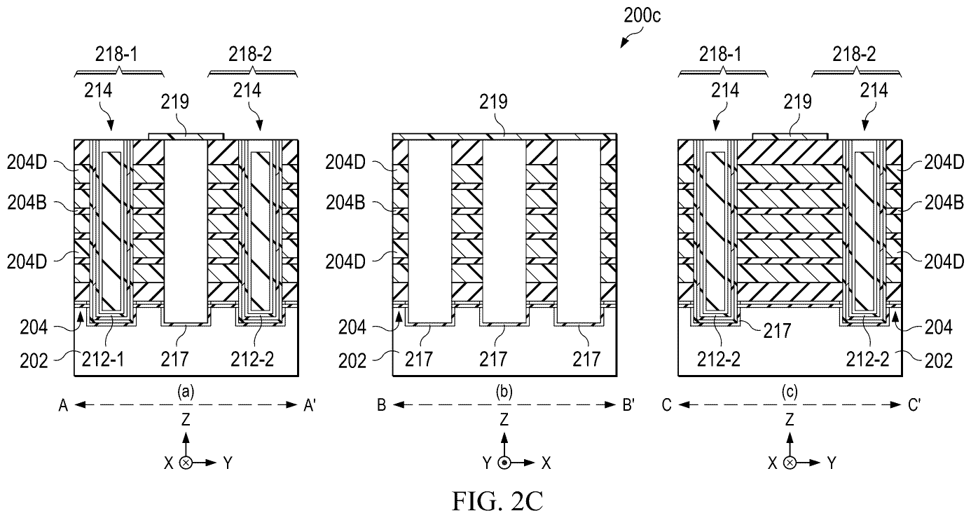

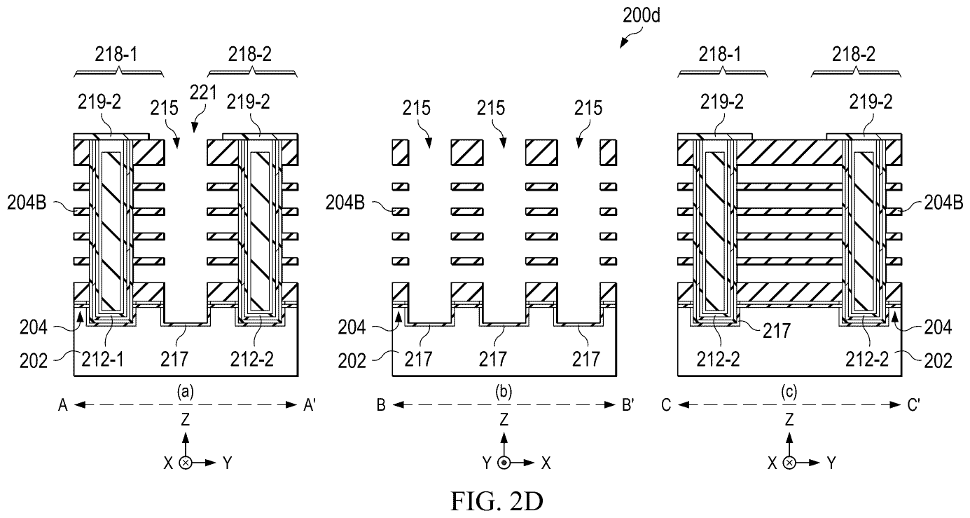

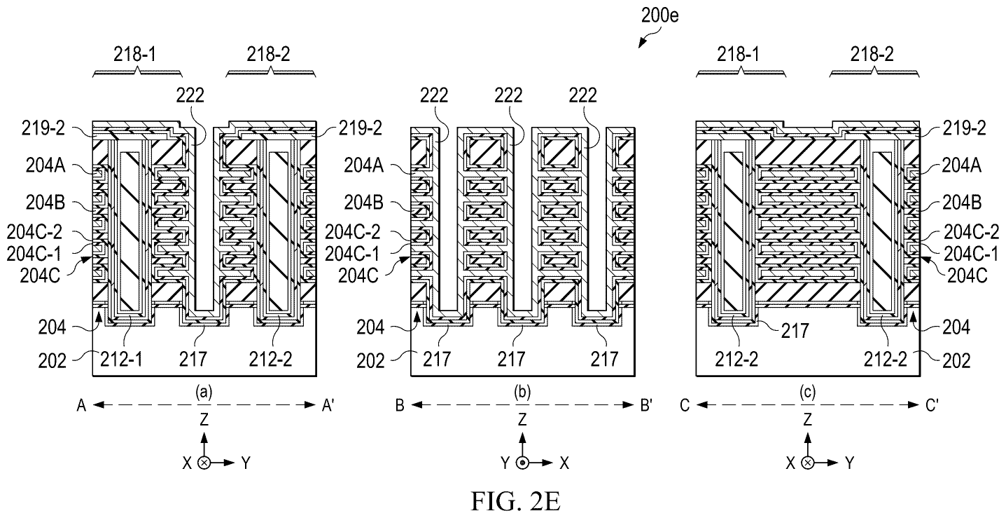

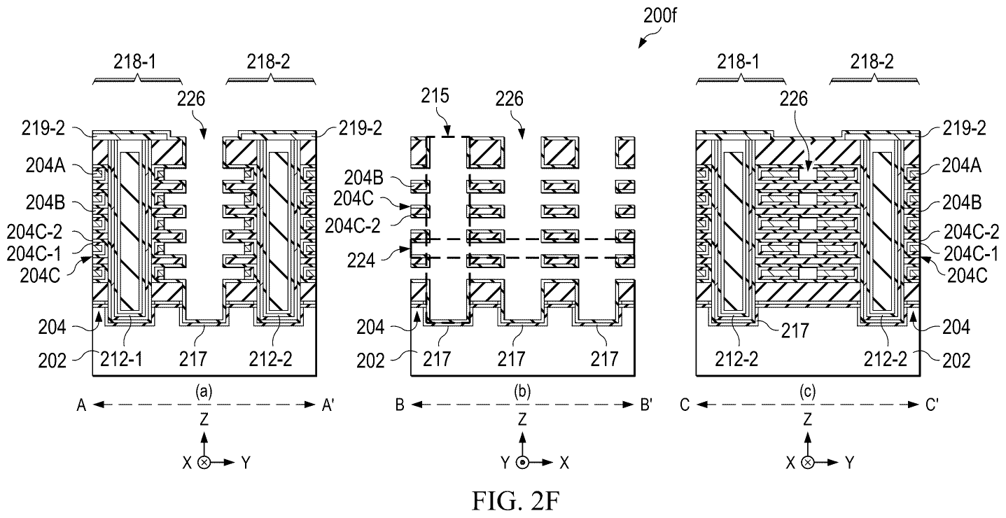

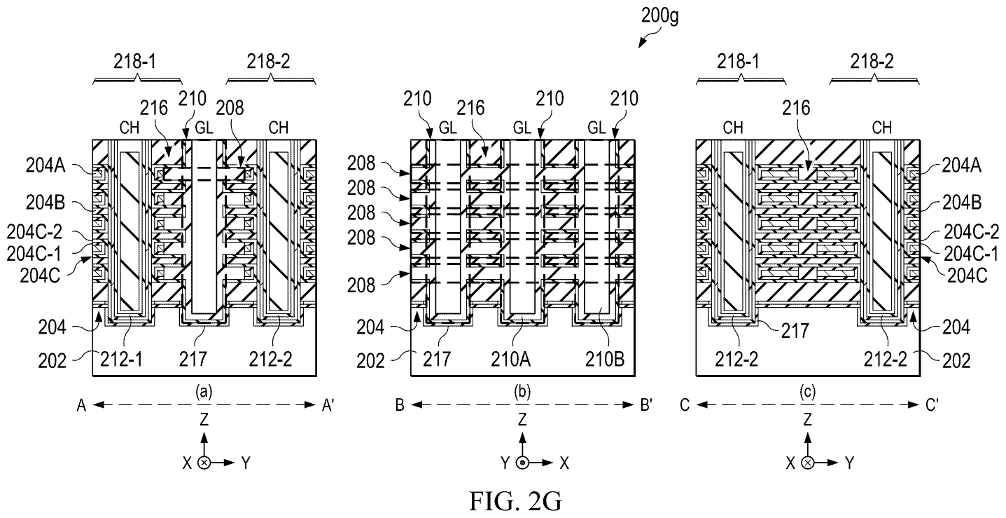

FIGS. 2A-2G illustrate an example process of fabricating a semiconductor device, such as the semiconductor device 100 as illustrated in FIGS. 1A-1B. FIGS. 2A-2G show cross-sectional views of example semiconductor structures at various stages of the fabrication process.

Specifically, FIGS. 2A(a)-2G(a) illustrate cross-sectional views of example semiconductor structures along the cut line AA′ of FIG. 1A, FIGS. 2A(b)-2G(b) illustrate cross-sectional views of the example semiconductor structures along the cut line BB′ of FIG. 1A, and FIGS. 2A(c)-2G(c) illustrate cross-sectional views of the example semiconductor structures along the cut line CC′ of FIG. 1A.

As shown in FIGS. 2A(a)-(c), a semiconductor structure 200a is provided. The semiconductor structure 200a includes a first portion 218-1 and a second portion 218-2 arranged along the Y direction. The semiconductor structure 200a includes a substrate 202 and a stack 204 of alternating sacrificial layers 204D and insulating layers 204B provided over the substrate 102. The stack 204 can extend across both the first portion 218-1 and the second portion 218-2. The sacrificial layers 204D and the insulating layers 204B can alternate in the vertical direction (e.g., the Z direction). The insulating layers 204B can include dielectric material, such as silicon oxide, silicon nitride, silicon oxynitride, or any combination thereof. In some implementations, the sacrificial layers 204D can include a dielectric material different from the dielectric material of the insulating layers 204B. For example, the insulating layers 204B can include silicon oxide, and the sacrificial layers 204D can include silicon nitride.

The semiconductor structure 200a can include a first array of channel holes 213-1 in the first portion 218-1 and a second array of channel holes 213-2 in the second portion 218-2. The semiconductor structure 200a can further include gate line holes 215 arranged and spaced along a line extending in the X direction between the first portion 218-1 and the second portion 218-2. The first array of channel holes 213-1, the second array of channel holes 213-2, and the gate line holes 215 can extend through the stack 204 and into the substrate 202 along the Z direction. In some implementations, the first array of channel holes 213-1, the second array of channel holes 213-2, and the gate line holes 215 can be formed by a same etching process. For example, the first array of channel holes 213-1, the second array of channel holes 213-2, and the gate line holes 215 can be formed by an etching process using one etching mask (not shown in FIG. 2A) applied on top of the semiconductor structure 200a. The etching mask can have patterns designed for these holes. The holes are formed by the etching process to extend through the sacrificial layers 204D and the insulating layer 204B of the stack 204 and down into the substrate 202.

As shown in FIGS. 2B(a)-(c), a semiconductor structure 200b can be formed by filling a filler material (e.g., polysilicon) into the first array of channel holes 213-1, the second array of channel holes 213-2, and the gate line holes 215 of the semiconductor structure 200a. In some implementations, before filling the filler material, protection structures 217 can be formed on bottoms (which are in contact with the substrate 202) of the channel holes 213-1 and 213-2 and the gate line holes 215 to protect the substrate 202. For example, the protection structures 217 can be formed using ploy oxidation. A sacrificial film 219 can be deposited on top of the semiconductor structure 200a to cover the first array of channel holes 213-1, the second array of channel holes 213-2, and the gate line holes 215.

As shown in FIGS. 2C(a)-(c), a semiconductor structure 200c including channel structures in the channel holes 213-1 and 213-2 can be formed. The channel structures can include a first array of channel structures 212-1 formed in the first array of channel holes 213-1 and a second array of channel structures 212-2 formed in the second array of channel holes 213-2. The channel structures 212-1 and 212-2 can be formed as follows: channel openings 214 are formed in the sacrificial film 219 to expose the channel holes 213-1 and 213-2; the filler material in the channel holes 213-1 and 213-2 are removed; and components of a channel structure, such as a high-K layer, a block layer, a charge trapping layer, a tunneling layer, a channel layer, a core filler layer, and a channel contact can be filled into each of the channel holes 213-1 and 213-2 subsequently.

As shown in a semiconductor structure 200d in FIGS. 2D(a)-(c), a new sacrificial film 219-2 can be formed on top of the semiconductor structure 200c to cover the first array of channel structures 212-1 and the second array of channel structures 212-2. Gate line openings 221 are formed in the sacrificial film 219-2 to expose the gate line holes 215. The filler material in the gate line holes 215 can be removed. The sacrificial layers 204D of the stack 204 can be removed by an etching process. The etching process can be performed, for example, by filling an etchant into the gate line holes 215.

As shown in FIGS. 2E(a)-(c), a semiconductor structure 200e is formed. The stack 204 of the semiconductor structure 200e includes conductive layers 204A between the insulating layers 204B. The conductive layers 204A and the insulating layers 204B alternate with each other along the vertical direction (e.g., the Z direction). In other words, the sacrificial layers 204D of the stack 204 in the semiconductor structure 200c are now replaced by the conductive layers 204A. The semiconductor structure 200e includes conductive inner surfaces 222 (also referred to as conductive inner layers) formed in the gate line holes 215. Each conductive inner layer 222 are in contact with an interior of a corresponding gate line hole 215. The conductive layers 204A are connected by the conductive inner layers 222. The conductive layers 204A and the conductive inner layers 222 can be formed by depositing at least one conductive material (e.g., W) into the gate line holes 215. In some implementations, before forming the conductive layers 204A, a high-K dielectric material (e.g., Al₂O₃) can be deposited on the surface of the insulating layers 204B and on the inner surfaces of the gate line holes 215 to form liner layers 204C. The conductive layers 204A can be in contact with the liner layers 204C. In some implementations, each liner layer 204C can include an adhesive material (e.g., TiN) and a high-K dielectric material. For example, as shown in FIGS. 2E(a)-(c), the liner layer 204C includes a layer 204C-1 and a layer 204C-2. The layer 204C-1 is made of the high-K material and is in contact with the surface of the insulating layers 204B and the inner surfaces of the gate line holes 215. The layer 204C-2 is made of the adhesive material. The layer 204C-1 can add protection to the conductive layers 204A and increase breakdown voltages of the conductive layers 204A. The layer 204C-2 can enhance the connection between the liner layers 204C and the conductive layers 204A.

As shown in FIGS. 2F(a)-(c), a semiconductor structure 200f is formed by performing an etching process to etch off the conductive inner layers 222. For example, the etching process can be performed by filling an etchant into the gate line holes 215. The etching process can further expose and recess the conductive layers 204A and form tunnels 224. Each of the tunnels 224 extends in the X-Y plane and is between two adjacent insulating layers 204B. The gate line holes 215 extend through the tunnels 224 along the vertical direction (e.g., the Z direction). A space formed by the tunnels 224 and the gate line holes 215 can be referred to as a gate line space 226 as shown in FIGS. 2F(a)-(c). As shown in FIGS. 2F(a) and 2F(b), the gate line space 226 can divide the conductive layers 204A into a first set of conductive layers and a second set of conductive layers. The first set of conductive layers are in the portion 218-1 of semiconductor structure 200f. The first array of channel structures 212-1 extend through the first set of conductive layers along the Z direction. The second set of conductive layers are in the portion 218-2 of semiconductor structure 200f. The second array of channel structures 212-2 extend through the second set of conductive layers along the Z direction. The first set of conductive layers in the portion 218-1 and the second set of conductive layers in the portion 218-2 are electrically isolated by the gate line space 226.

In some implementations, depending on selection of the etchant, part of the liner layers 204C can also be removed by the etching process. For example, as shown in FIGS. 2F(a)-(c), part of adhesive material (e.g., layers 204C-2) of the liner layers 204C can be removed. In some other examples (not shown in FIGS. 2F(a)-(c)), part of the high-K material (e.g., layers 204C-1) of the liner layers 204C also can be removed.

As shown in FIGS. 2G(a)-(c), a semiconductor structure 200g is formed. The semiconductor structure 200g can be similar to, or same as the semiconductor device 100 as shown in FIGS. 1A-1B. The portion 218-1 and the portion 218-2 of the semiconductor structure 200g can be similar to, or same as the memory block 118-1 and the memory block 118-2 of the semiconductor device 100, respectively. The semiconductor structure 200g includes a gate line structure 216 in the gate line space 226. The gate line structure 216 can be similar to, or same as the gate line structure 116 of FIGS. 1A-1B. For example, the gate line structure 216 includes gate line insulating layers 208 formed in the tunnels 224 and pillars 210 formed in the gate line holes 215. The pillars 210 extend through the gate line insulating layers 208 along the vertical direction. Each gate line insulating layer 208 can be between a corresponding conductive layer 204A in the portion 218-1 and a corresponding conductive layer 204A in the portion 218-2 along the Y direction. Each pillar 210 can include an outer layer 210A connected to the gate line insulating layers 208 and an inner structure 210B surrounded by the outer layer 210A. The gate line structure 216 can be similar to, or same as the gate line structure 116 of the semiconductor device 100. The pillars 210 can be similar to, or same as the pillars 110 of the semiconductor device 100.

In some implementations, the gate line insulating layers 208 and the outer layer 210A of each of the pillars 210 can be formed by depositing a dielectric material in the gate line space 226 through the gate line holes 215. The inner structure 210B of each of the pillars 210 can be formed by filling a filler material into the remaining space of the gate line holes 215. The filler material can include at least one of a polycrystalline silicon material, a dielectric material, or a metal. It is understood that while FIG. 2G illustrates that semiconductor structure 200g includes two memory blocks 218-1 and 218-2 and one gate line structure 216, in practice a semiconductor device can include any suitable number of memory blocks and any suitable number of gate line structures.

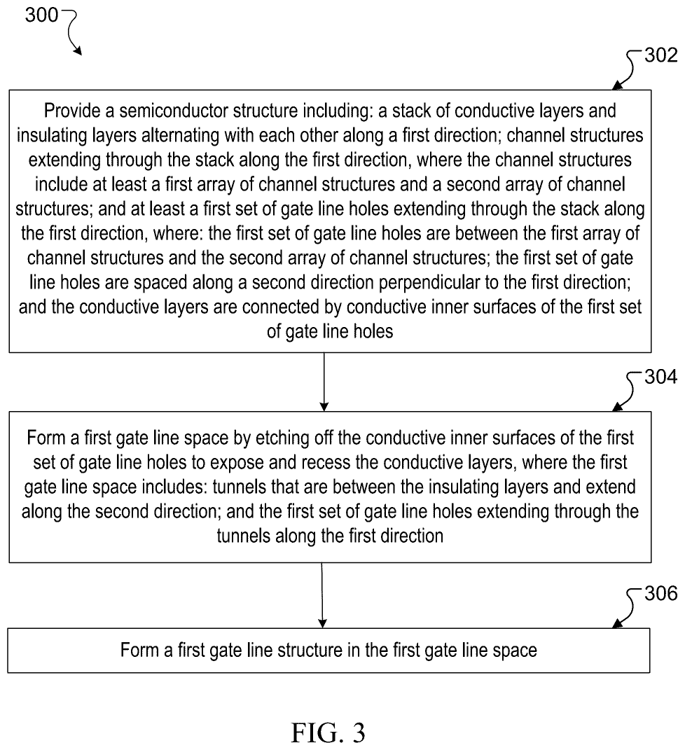

FIG. 3 illustrates a flow chart of an example process 300. The process 300 can be performed to form a semiconductor device. The semiconductor device can be similar to, or same as, the semiconductor device 100 of FIGS. 1A-1B. The process 300 can be described in view of FIGS. 2A-2G. The process 300 can include one or more steps of the fabrication process of forming the semiconductor structures in FIGS. 2A-2G. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a semiconductor structure (e.g., the semiconductor structure 200e of FIG. 2E) is provided. The semiconductor structure can include a stack (e.g., the stack 204 of FIG. 2E) of conductive layers (e.g., the conductive layers 204A of FIG. 2E) and insulating layers (e.g., the insulating layers 204B of FIG. 2E) alternating with each other along a first direction (e.g., the Z direction), channel structures extending through the stack along the first direction, and at least a first set of gate line holes (e.g., the gate line holes 215 of FIG. 2E) extending through the stack along the first direction. The channel structures include at least a first array of channel structures (e.g., the array of channel structures 212-1 of FIG. 2E) and a second array of channel structures (e.g., the array of channel structures 212-2 of FIG. 2E). The first set of gate line holes is between the first array of channel structures and the second array of channel structures. The first set of gate line holes is spaced along a second direction (e.g., the X direction) perpendicular to the first direction. The conductive layers are connected by conductive inner surfaces (the conductive inner surfaces 222 of FIG. 2E) of the first set of gate line holes.

In some implementations, providing the semiconductor structure includes forming a stack (e.g., the stack 204 of FIG. 2A) of sacrificial layers (e.g., the sacrificial layers 204D of FIG. 2A) and insulating layers (e.g., the insulating layers 204B of FIG. 2A) alternating with each other along the first direction. Providing the semiconductor structure further includes forming gate line holes (e.g., the gate line holes 215 of FIG. 2A) and channel holes (e.g., the channel holes 213-1 and 213-2 of FIG. 2A) by a same etching process. The gate line holes and the channel holes extend through the stack of sacrificial layers and insulating layers along the first direction. The gate line holes include the first set of gate line holes. Providing the semiconductor structure further includes forming the channel structures (e.g., the channel structures 212-1 and 212-2 of FIG. 2C) in the channel holes.

In some implementations, providing the semiconductor structure further includes removing the sacrificial layers (e.g., as described with reference to FIG. 2D) and forming the conductive layers and the conductive inner surfaces of the first set of gate line holes by depositing at least one conductive material into the first set of gate line holes (e.g., as described with reference to FIG. 2E).

At operation 304, a first gate line space (e.g., the gate line space 226 of FIG. 2F) is formed by etching off the conductive inner surfaces of the first set of gate line holes to expose and recess the conductive layers. The first gate line space includes tunnels (e.g., the tunnels 224 of FIG. 2F) that are between the insulating layers (e.g., the insulating layers 204B of FIG. 2F) and extend along the second direction and the first set of gate line holes (e.g., the gate line holes 215 of FIG. 2F) extending through the tunnels along the first direction.

At operation 306, a first gate line structure (e.g., the gate line structure 216 of FIG. 2G) is formed in the first gate line space.

In some implementations, the first gate line space divides the conductive layers into a first set of conductive layers (e.g., the conductive layers 204A in the portion 218-1 of FIG. 2F) extended through by the first array of channel structures (e.g., the array of channel structures 212-1 of FIG. 2F) and a second set of conductive layers (e.g., the conductive layers 204A in the portion 218-2 of FIG. 2F) extended through by the second array of channel structures (e.g., the array of channel structures 212-2 of FIG. 2F).

In some implementations, the first gate line structure includes gate line insulating layers (e.g., the gate line insulating layers 208 of FIG. 2G) in the tunnels and pillars (e.g., the pillars 210 of FIG. 2G) in the first set of gate line holes. Each of the pillars includes an outer layer (e.g., the outer layer 210A of FIG. 2G) connected to the gate line insulating layers and an inner structure (e.g., the inner structure 210B of FIG. 2G) surrounded by the outer layer.

In some implementations, forming the first gate line structure includes forming the gate line insulating layers and the outer layer of each of the pillars by depositing a dielectric material in the first gate line space through the first set of gate line holes. Forming the first gate line structure further includes forming the inner structure of each of the pillars by filling at least one of a polycrystalline silicon material, a dielectric material, or a metal into the first set of gate line holes.

In some implementations, forming the channel structures in the channel holes includes
filling the gate line holes (e.g., the gate line holes 215 of FIG. 2A) and the channel holes (e.g., the channel holes 213-1 and 213-2 of FIG. 2A) with a sacrificial material, covering the gate line holes (e.g., using the sacrificial film 219 of FIG. 2C), removing the sacrificial material in the channel holes (e.g., as described with reference to FIG. 2C), and depositing a high-k material, a memory film, and a channel layer into each of the channel holes (e.g., as described with reference to FIG. 2C).

In some implementations, the channel structures further include a third array of channel structures, and the gate line holes further include a second set of gate line holes between the second array of channel structures and the third array of channel structures.

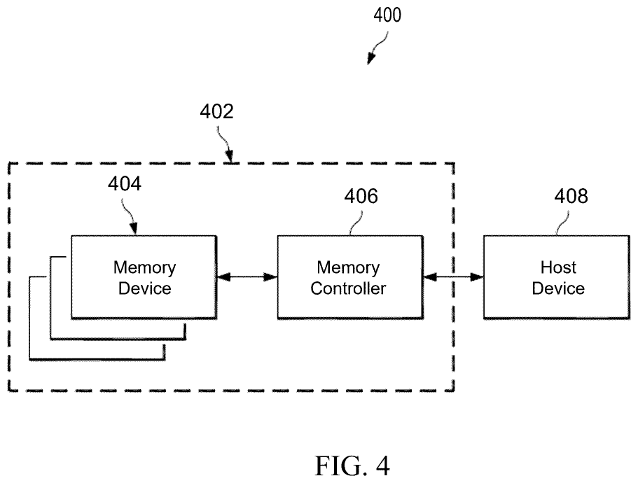

FIG. 4 illustrates a block diagram of an example system 400. The system 400 can have one or more semiconductor devices (e.g., memory devices), according to one or more implementations of the present disclosure. The system 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 4, the system 400 can include a host device 408 and a memory system 402 having one or more memory devices 404 and a memory controller 406. Host device 408 can include a processor of an electronic device, such as a central processing unit (CPU), or a system-on-chip (SoC), such as an application processor (AP). Host device 408 can be configured to send or receive data to or from the one or more memory devices 404.

A memory device 404 can be any memory device disclosed herein, such as a memory device (e.g., a NAND Flash memory) as shown in FIGS. 1A-1B. Memory controller 406 (a.k.a., a controller circuit) is coupled to memory device 404 and host device 408. Consistent with implementations of the present disclosure, memory device 404 can include a plurality of conductive interconnections through a cover layer that are in contact with conductive pads in a conductive pad layer, and memory controller 406 can be coupled to memory device 404 through at least one of the plurality of conductive interconnections. Memory controller 406 is configured to control memory device 404. For example, memory controller 406 may be configured to operate a plurality of channel structures via word lines. Memory controller 406 can manage data stored in memory device 404 and communicate with host device 408.

In some implementations, memory controller 406 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program (or write) operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404.

Memory controller 406 can communicate with an external device (e.g., host device 408) according to a particular communication protocol. For example, memory controller 406 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 4, memory controller 406 and a single memory device 404 may be integrated into a memory card 402. Memory card 402 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value). In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
memory blocks comprising at least a first memory block and a second memory block, wherein each of the first memory block and the second memory block comprises a stack of conductive layers and insulating layers alternating with each other along a first direction; and
at least a first gate line structure between the first memory block and the second memory block, wherein the first gate line structure insulates the conductive layers of the first memory block from the conductive layers of the second memory block, and the first gate line structure comprises:
gate line insulating layers spaced along the first direction; and
pillars that are spaced along a second direction perpendicular to the first direction and extend through the gate line insulating layers along the first direction.

2. The semiconductor device of claim 1, wherein the first gate line structure is in contact with a sidewall of the first memory block and a sidewall of the second memory block.

3. The semiconductor device of claim 1, wherein a gate line insulating layer of the gate line insulating layers is between a corresponding conductive layer of the first memory block and a corresponding conductive layer of the second memory block.

4. The semiconductor device of claim 1, wherein a pillar of the pillars comprises an outer layer and an inner structure surrounded by the outer layer, the outer layer comprises a dielectric material, and the inner structure comprises at least one of a polycrystalline silicon material, a dielectric material, or a metal.

5. The semiconductor device of claim 1, wherein one of the gate line insulating layers comprises a dielectric material.

6. The semiconductor device of claim 1, further comprising a third memory block and a second gate line structure between the second memory block and the third memory block.

7. The semiconductor device of claim 1, further comprising one or more other gate line structures, wherein the first memory block comprises multiple memory fingers divided by the one or more other gate line structures.

8. The semiconductor device of claim 1, wherein the stack of conductive layers and insulating layers comprises multiple decks stacked along the first direction, and each of the multiple decks comprises a subset of the stack of conductive layers and insulating layers.

9. A method for fabricating a semiconductor device, comprising:
providing a semiconductor structure comprising:
a stack of conductive layers and insulating layers alternating with each other along a first direction;
channel structures extending through the stack along the first direction, wherein the channel structures comprise at least a first array of channel structures and a second array of channel structures; and
at least a first set of gate line holes extending through the stack along the first direction, wherein:
the first set of gate line holes is between the first array of channel structures and the second array of channel structures;
the first set of gate line holes is spaced along a second direction perpendicular to the first direction; and
the conductive layers are connected by conductive inner surfaces of the first set of gate line holes;
forming a first gate line space by etching off the conductive inner surfaces of the first set of gate line holes to expose and recess the conductive layers, wherein the first gate line space comprises: tunnels that are between the insulating layers and extend along the second direction, and the first set of gate line holes extending through the tunnels along the first direction; and
forming a first gate line structure in the first gate line space.

10. The method of claim 9, wherein the first gate line space divides the conductive layers into a first set of conductive layers extended through by the first array of channel structures and a second set of conductive layers extended through by the second array of channel structures.

11. The method of claim 9, wherein the first gate line structure comprises:
gate line insulating layers in the tunnels; and
pillars in the first set of gate line holes, wherein each of the pillars comprises an outer layer connected to the gate line insulating layers and an inner structure surrounded by the outer layer.

12. The method of claim 11, wherein forming the first gate line structure comprises:
forming the gate line insulating layers and the outer layer of each of the pillars by depositing a dielectric material in the first gate line space through the first set of gate line holes; and
forming the inner structure of each of the pillars by filling at least one of a polycrystalline silicon material, a dielectric material, or a metal into the first set of gate line holes.

13. The method of claim 9, wherein providing the semiconductor structure comprises:
forming a stack of sacrificial layers and insulating layers alternating with each other along the first direction;
forming gate line holes and channel holes by a same etching process, wherein the gate line holes and the channel holes extend through the stack of sacrificial layers and insulating layers along the first direction, and the gate line holes comprise the first set of gate line holes; and
forming the channel structures in the channel holes.

14. The method of claim 13, wherein providing the semiconductor structure further comprises:
removing the sacrificial layers; and
forming the conductive layers and the conductive inner surfaces of the first set of gate line holes by depositing at least one conductive material into the first set of gate line holes.

15. The method of claim 13, wherein the channel structures further comprise a third array of channel structures, and the gate line holes further comprise a second set of gate line holes between the second array of channel structures and the third array of channel structures.

16. The method of claim 13, wherein forming the channel structures in the channel holes comprises:
filling the gate line holes and the channel holes with a sacrificial material;
covering the gate line holes;
removing the sacrificial material in the channel holes; and
depositing a high-k material, a memory film, and a channel layer into each of the channel holes.

17. A memory system comprising:
a memory device; and
a memory controller coupled to the memory device and configured to control the memory device,
wherein the memory device comprises:
memory blocks comprising at least a first memory block and a second memory block, wherein each of the first memory block and the second memory block comprises a stack of conductive layers and insulating layers alternating with each other along a first direction; and
at least a first gate line structure between the first memory block and the second memory block, wherein the first gate line structure insulates the conductive layers of the first memory block from the conductive layers of the second memory block, and the first gate line structure comprises:
gate line insulating layers spaced along the first direction; and
pillars that are spaced along a second direction perpendicular to the first direction and extend through the gate line insulating layers along the first direction.

18. The memory system of claim 17, wherein a gate line insulating layer of the gate line insulating layers is between a corresponding conductive layer of the first memory block and a corresponding conductive layer of the second memory block.

19. The memory system of claim 17, wherein a pillar of the pillars comprises an outer layer and an inner structure surrounded by the outer layer, the outer layer comprises a dielectric material, and the inner structure comprises at least one of a polycrystalline silicon material, a dielectric material, or a metal.

20. The memory system of claim 17, wherein the memory device further comprises a third memory block and a second gate line structure between the second memory block and the third memory block.
